(19) United States
(12) Patent Application Publication
(10) Pub. No.: US 2026/0211334 A1
(43) Pub. Date: Jul. 23, 2026

(54) STRIPPER COMPOSITION AND METHOD OF FORMING PATTERN USING THE SAME

(71) Applicants: Samsung Display Co., LTD., Yongin-si (KR); LTC Co., Ltd, Hwaseong-si (KR)

(72) Inventors: Kyu Soon PARK, Yongin-si (KR); Kyu Sang KIM, Anyang-si (KR); Byung Woo JEON, Uiwang-si (KR); Yeon Soo CHOI, Seongnam-si (KR); Young Rok KIM, Yongin-si (KR); Jong Hyun CHOUNG, Yongin-si (KR); Woo Jin CHO, Yongin-si (KR)

(21) Appl. No.: 19/431,334

(22) Filed: Dec. 23, 2025

(30) Foreign Application Priority Data
Jan. 20, 2025 (KR) 10-2025-0008192

(51) Int. Cl. G03F 7/42; C11D 7/26; C11D 7/32

(52) U.S. Cl. CPC G03F 7/425; C11D 7/261; C11D 7/263; C11D 7/3209; C11D 7/3218; C11D 2111/22

(57) ABSTRACT

A stripper composition includes about 5 wt % to about 15 wt % of an amine compound having a molecular weight of about 80 g/mol or less and a Hansen Solubility parameter (HSPₒ) value in a range from about 27 to about 32, about 1 wt % to about 10 wt % of a tetra-ammonium salt, about 5 wt % to about 15 wt % of a cyclic alcohol, about 10 wt % to about 50 wt % of a protic polar organic solvent, about 10 wt % to about 50 wt % of an aprotic polar organic solvent, and about 0.05 wt % to about 1 wt % a polyhydric alcohol having 4 to 6 carbon atoms, based on a total weight of 100 wt % of the stripper composition.

### CROSS-REFERENCE TO RELATED APPLICATION AND CLAIM OF PRIORITY

The present application claims priority to and the benefit of Korean Patent Application No. 10-2025-0008192, filed on Jan. 20, 2025, in the Korean Intellectual Property Office (KIPO), the entire disclosure of which is incorporated herein by reference.

### TECHNICAL FIELD

One or more embodiments of the present disclosure relate to a stripper composition and a method of forming a pattern using the same. For example, one or more embodiments of the present disclosure relate to a stripper composition capable of removing an organic layer and a method of forming a pattern using the same.

### BACKGROUND

In the fabrication of semiconductor devices and display panels (e.g., a panel of a display device), a photolithography process involving a photoresist is commonly employed. For example, a photoresist layer may be formed on a substrate, and the photoresist layer may be exposed and developed to form a photoresist pattern.

A stripper composition is used to remove the photoresist pattern during the photolithography process. Comparable stripper compositions often contain environmentally regulated substances. Accordingly, there is a need or desire for stripper compositions that exhibit improved photoresist removal performance while reducing or minimizing the presence of environmentally regulated substances.

### SUMMARY

One or more aspects of embodiments of the present disclosure are directed toward a stripper composition that has improved stripping and eco-friendly properties.

One or more aspects of embodiments of the present disclosure are directed toward a method of forming a pattern using the stripper composition.

Additional aspects will be set forth in part in the description which follows and, in part, will be apparent from the description, or may be learned by practice of the presented embodiments of the disclosure.

According to one or more embodiments of the present disclosure, a stripper composition may include about 5 wt % to about 15 wt % of an amine compound having a molecular weight of about 80 g/mol or less and a Hansen Solubility parameter (HSPₒ) value defined by Equation 1 in a range from about 27 to about 32, about 1 wt % to about 10 wt % of a tetra-ammonium salt (e.g., quaternary ammonium salt), about 5 wt % to about 15 wt % of a cyclic alcohol, about 10 wt % to about 50 wt % of a protic polar organic solvent, about 10 wt % to about 50 wt % of an aprotic polar organic solvent, and about 0.05 wt % to about 1 wt % a polyhydric alcohol having 4 to 6 carbon atoms, based on a total weight of 100 wt % of the stripper composition.

$$H S {P}_{o} = {( H S {P}_{d}^{2} + H S {P}_{p}^{2} + H S {P}_{h}^{2} )}^{0.5} \qquad Equation 1$$

In Equation 1, HSP_{d} represents a solubility factor caused by a nonpolar dispersion bonding. HSPₚ represents a solubility factor caused by a polar bonding due to permanent dipoles, and HSPₕ represents a solubility factor caused by a hydrogen bonding.

In one or more embodiments, the amine compound may include an alkanol amine compound.

In one or more embodiments, the amine compound may include at least one selected from among monoisopropanolamine (1-aminopropan-2-ol), 3-amino-1-propanol, monoethanolamine (2-aminoethanol), and 2-methylaminoethanol.

In one or more embodiments, the amine compound may include a primary amine compound.

In one or more embodiments, the tetra-ammonium salt may include four organic substituents and one anion, and the four organic substituents may each independently be an alkyl group or an aryl group, and the anion may be a chloride ion, a bromide ion, an iodide ion, or a hydroxide ion.

In one or more embodiments, the tetra-ammonium salt may include at least one of tetramethylammonium hydroxide, tetraethylammonium hydroxide, tetrapropylammonium hydroxide, tetrabutylammonium hydroxide, cetyltrimethylammonium bromide, a benzalkonium chloride, dodecyltrimethylammonium chloride, tetrabutylammonium bromide, tetrabutylammonium iodide, and tetraethylammonium chloride.

In one or more embodiments, the number of carbons of the cyclic alcohol may be in a range from 4 to 6.

In one or more embodiments, the cyclic alcohol may include at least one of tetrahydrofurfuryl alcohol, furfuryl alcohol, cyclobutanol, cyclopentanol, cyclohexanol, or isopropylideneglycerol.

In one or more embodiments, the protic polar organic solvent may include a glycol-based compound represented by Chemical Formula 1 or Chemical Formula 2.

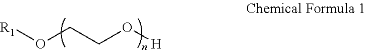

In Chemical Formula 1, R₁ may be hydrogen, a substituted or unsubstituted alkyl group having 1 to 10 carbon atoms, a substituted or unsubstituted cycloalkyl group having 3 to 15 carbon atoms, or a substituted or unsubstituted aryl group having 3 to 15 carbon atoms, and n is an integer of 1 or greater.

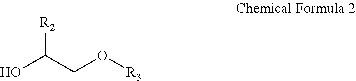

In Chemical Formula 2, R₂ may be hydrogen, a substituted or unsubstituted alkyl group having 1 to 10 carbon atoms, and R₃ may be hydrogen, a substituted or unsubstituted alkyl group having 1 to 10 carbon atoms, or a substituted or unsubstituted alkoxy group having 1 to 10 carbon atoms.

In one or more embodiments, the protic polar organic solvent may include at least one of ethylene glycol, propylene glycol, diethylene glycol monoethyl ether, diethylene glycol monobutyl ether, diethylene glycol monomethyl ether, ethylene glycol monoethyl ether, ethylene glycol monobutyl ether, propylene glycol monomethyl ether, propylene glycol monoethyl ether, propylene glycol monobutyl ether, diethylene glycol monopropyl ether, dipropylene glycol monomethyl ether, dipropylene glycol monoethyl ether, dipropylene glycol monopropyl ether, dipropylene glycol monobutyl ether, triethylene glycol monopropyl ether, triethylene glycol monobutyl ether, triethylene glycol monomethyl ether, tripropylene glycol monoethyl ether, tripropylene glycol monopropyl ether, or tripropylene glycol monobutyl ether.

In one or more embodiments, the stripper composition may not include (e.g., may exclude) N-methyl-2-pyrrolidone and N-methylformamide.

In one or more embodiments, the aprotic polar organic solvent may include at least one of 2-pyrrolidone, 4-formylmorpholine, N,N-dimethyl propionamide, 1,3-dimethyl-2-imidazolidinone, N,N-dimethylacetoacetamide, sulfolane, N-ethylformamide, or 3-methoxy N,N-dimethylpropanamide (Equamide).

In one or more embodiments, the polyhydric alcohol may be a linear alkyl alcohol.

In one or more embodiments, the polyhydric alcohol may include at least one of erythritol, threitol, arabitol, xylitol, ribitol, mannitol, sorbitol, galactitol, fucitol, or iditol.

In one or more embodiments, the stripper composition may not include (may exclude) water.

According to one or more embodiments, in a method of forming a pattern, an etching target layer may be formed on a substrate. A photoresist pattern may be formed on the etching target layer. The etching target layer may be etched using the photoresist pattern. The photoresist pattern may be removed using a stripper composition. The stripper composition may include about 5 wt % (weight percentage) to about 15 wt % of an amine compound having a molecular weight of about 80 g/mol or less and a Hansen Solubility parameter (HSPₒ) value defined by Equation 1 in a range from about 27 to about 32, about 1 wt % to about 10 wt % of a tetra-ammonium salt (e.g., quaternary ammonium salt), about 5 wt % to about 15 wt % of a cyclic alcohol, about 10 wt % to about 50 wt % of a protic polar organic solvent, about 10 wt % to about 50 wt % of an aprotic polar organic solvent, and about 0.05 wt % to about 1 wt % a polyhydric alcohol having 4 to 6 carbon atoms, based on a total weight of 100 wt % of the stripper composition.

$$H S {P}_{o} = {( H S {P}_{d}^{2} + H S {P}_{p}^{2} + H S {P}_{h}^{2} )}^{0.5} \qquad Equation 1$$

In Equation 1, HSP_{d} represents a solubility factor caused by a nonpolar dispersion bonding. HSPₚ represents a solubility factor caused by a polar bonding caused by permanent dipoles, and HSPₕ represents a solubility factor caused by a hydrogen bonding.

A stripper composition according to one or more embodiments of the present disclosure may include an amine compound having a molecular weight of about 80 g/mol or less and a Hansen solubility factor (HSPₒ) value of about 27 to about 32 according to Equation 1, and a tetra-ammonium salt to provide enhanced stripping properties. The composition enhances stripping performance by promoting the dissolution and detachment of photoresist residues from the substrate surface. The combination of a low-molecular-weight amine compound with a tailored solubility profile and a tetra-ammonium salt enables effective removal of organic layers, including crosslinked or hardened photoresist films, while reducing or minimizing substrate damage and reducing environmental impact. The interaction between the amine compound and the tetra-ammonium salt may improve the overall stripping efficiency, particularly in semiconductor and display manufacturing processes where comparable strippers may fail to remove complex photoresist structures. Additionally, the exclusion of water and certain regulated solvents such as N-methyl-2-pyrrolidone (NMP) and/or N-methylformamide enhances the eco-friendly characteristics of the composition, making it suitable for utilization in environmentally conscious fabrication environments.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects, features, and advantages of certain embodiments of the disclosure will be more apparent from the following description taken in conjunction with the accompanying drawings, in which:

FIGS. 1-3 are schematic cross-sectional views describing a method of forming a pattern according to one or more embodiments of the present disclosure.

### DETAILED DESCRIPTION

The present disclosure may be modified in many alternate forms, and thus specific embodiments will be exemplified in the drawing and described in more detail. It should be understood, however, that it is not intended to limit the present disclosure to the particular forms disclosed, but rather, is intended to cover all modifications, equivalents, and alternatives falling within the spirit and scope of the present disclosure.

Hereinafter, one or more embodiments of the present disclosure will be described in more detail with reference to the accompanying drawings. The same or like reference numerals may be used for indicating the same or like elements in the drawings, and repeated descriptions of the same elements may not be provided for conciseness. Embodiments disclosed in the accompanying drawings are example, and are to be understood to include all modifications, equivalents, and substitutes included within the spirit and technical scope of the present disclosure.

The terms “on”, “connected”, “coupled,” and/or the like. as used herein refers to a direct placement/connection/combination, and also refers to embodiments in which one or more other elements are interposed two different elements.

The terms such as “first”, “second”, “below”, “lower”, “upper”, “above”, “top”, “bottom”, and/or the like, are used in a relative sense to distinguish different elements or positions, and do not specify an absolute position or an absolute order.

In the present disclosure, the term “substituted or unsubstituted” may refer to being substituted or unsubstituted with one or more substituents selected from the group consisting of deuterium, a halogen, a cyano group, a nitro group, an amino group, a silyl group, a hydroxyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the above-mentioned substituents may be substituted or unsubstituted. For example, a biphenyl group may be interpreted as an aryl group, or a phenyl group substituted with a phenyl group.

In the present disclosure, an alkyl group may be linear or branched. The number of carbon atoms in the alkyl group may be in a range from 1 to 50, from 1 to 30, from 1 to 20, from 1 to 10, or from 1 to 6. Examples of the alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, 1-methylpentyl, 3-methylpentyl, 2-ethylpentyl, 4-methyl-2-pentyl, n-hexyl, 1-methylhexyl, 2-ethylhexyl, 2-butylhexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl group, n-nonyl, n-decyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldodecyl, 2-octyldodecyl, n-tridecyl, n-tetradecyl, n-pentadecyl, n-hexadecyl, 2-ethylhexadecyl, 2-butylhexadecyl, 2-hexylhexadecyl group, 2-octylhexadecyl, n-heptadecyl, n-octadecyl, n-nonadecyl, n-icosyl, 2-ethylicosyl, 2-butylicosyl, 2-hexylicosyl, 2-octyllicosyl, n-henicosyl, n-docosyl, n-tricosyl, n-tetracosyl, n-pentacosyl, n-hexacosyl, n-heptacosyl, n-octacosyl, n-nonacosyl, and n-triacontyl, but are not limited thereto.

In the present disclosure, a cycloalkyl group may refer to a cyclic alkyl group. The number of carbon atoms of the cycloalkyl group may be in a range from 3 to 50, from 3 to 30, from 3 to 20, or from 3 to 10. Examples of the cycloalkyl group may include, a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and/or the like, but are not limited thereto.

In the present disclosure, an alkenyl group may refer to a hydrocarbon group having at least one carbon-carbon double bond in the middle or at a terminal of an alkyl group having at least 2 carbon atoms. The alkenyl group may be linear or branched. The number of carbon atoms of the alkenyl group is not particularly limited, for example, may be in a range from 2 to 30, from 2 to 20, or from 2 to 10. Examples of the alkenyl group may include, a vinyl group, a 1-butenyl group, a 1-pentenyl group, a 1,3-butadienyl aryl group, a styrenyl group, a styrylvinyl group, and/or the like, but are not limited thereto,

In the present disclosure, an alkynyl group may refer to a hydrocarbon group having at least one carbon-carbon triple bond in the middle or at a terminal of an alkyl group having at least 2 carbon atoms. The alkynyl group may be linear or branched. The number of carbon atoms of the alkynyl group is not particularly limited, for example, may be in a range from 2 to 30, from 2 to 20, or from 2 to 10. Examples of the alkynyl group may include an ethynyl group, a propynyl group, and/or the like, but are not limited thereto.

In the present disclosure, a hydrocarbon ring group may refer to any functional group or substituent derived from an aliphatic hydrocarbon ring. The hydrocarbon ring group may be a saturated hydrocarbon ring group having 3 to 20 ring-forming carbon atoms, or 3 to 15 ring-forming carbon atoms.

In the present disclosure, an aryl group may refer to any functional group or substituent derived from an aromatic hydrocarbon ring. The aryl group may be a monocyclic aryl group or a polycyclic aryl group. The aryl group may have 6 to 30 ring-forming carbon atoms, or 6 to 20 ring-forming carbon atoms, or 6 to 15 ring-forming carbon atoms. Examples of the aryl group may include, phenyl, naphthyl, fluorenyl, anthracenyl, phenanthryl, biphenyl, terphenyl, quarterphenyl, quinquephenyl, sexiphenyl, triphenylenyl, pyrenyl, benzofluoranthenyl, chrysenyl, and/or the like, but are not limited thereto.

In the present disclosure, an alkoxy group may have a straight chain structure, a branched chain structure, or a cyclic chain structure. The number of carbon atoms in the alkoxy group is not particularly limited, but may be, e.g., in a range from 1 to 20, or from 1 to 10. Examples of the alkoxy group may include, methoxy, ethoxy, n-propoxy, isopropoxy, butoxy, pentyloxy, hexyloxy, octyloxy, nonyloxy, decyloxy, benzyloxy, and/or the like, but embodiments of the present disclosure are not limited to.

Hereinafter, a stripper composition according to one or more embodiments of the present disclosure will be described in more detail.

The stripper composition according to one or more embodiments may be used to strip a photoresist pattern formed on an underlying layer. In one or more embodiments, the stripper composition may be used to strip a photoresist pattern formed on a metal layer or a metal oxide layer. In one or more embodiments, the stripper composition may be used to strip a photoresist pattern formed on an underlying layer including a combination of a metal layer and a metal oxide layer.

The underlying layer of the photoresist pattern may include a metal layer, a metal oxide layer, or a combination thereof, and may have a single-layered structure or a multi-layered structure. The metal layer may include a metal pattern.

The stripper composition may include an amine compound, a tetra-ammonium salt (e.g., quaternary ammonium salt), a cyclic alcohol, a protic polar organic solvent, an aprotic polar organic solvent, and a polyhydric alcohol.

The amine compound included in the stripper composition may reduce a bonding strength of the photoresist pattern. For example, an intermolecular bond in the photoresist resin cured (e.g., treated) by the amine compound may be decomposed and/or cut. Accordingly, the stripper composition including the amine compound may facilitate removal of the photoresist pattern.

In one or more embodiments, the amine compound may have a small molecular weight to enhance a stripping rate of the photoresist pattern, and may have a Hansen Solubility parameter value in a range from about 27 to about 32. The molecular weight may be a weight average molecular weight. The amine compound may have a low molecular weight and may have the Hansen Solubility parameter value in the above-described range, thereby improving the solubility and stripping rate of the photoresist pattern.

For example, the molecular weight of the amine compound may be about 80 g/mol or less. In one or more embodiments, the molecular weight of the amine compound may be in a range from about 30 g/mol to about 80 g/mol. In the above molecular weight range, the stripping rate may be increased. As the molecular weight of the amine compound becomes smaller within the above molecular weight range, a time for stripping the photoresist pattern may be decreased.

In one or more embodiments, the amine compound may have a Hansen Solubility parameter (HSPₒ) value according to Equation 1 in a range from about 27 to about 32. The amine compound having the Hansen Solubility parameter (HSPₒ) value according to Equation 1 that may satisfy the above-described range may increase the solubility of the photoresist pattern. Thus, the stripper composition including the amine compound may have an increased stripping rate.

$$H S {P}_{o} = {( H S {P}_{d}^{2} + H S {P}_{p}^{2} + H S {P}_{h}^{2} )}^{0.5} \qquad Equation 1$$

In Equation 1, HSP_{d} may be a solubility factor caused by a nonpolar dispersion bonding. HSPₚ may be a solubility factor caused by a polar bonding due to permanent dipoles. HSPₕ may be a solubility factor caused by a hydrogen bonding.

In one or more embodiments, the amine compound may have the Hansen Solubility parameter (HSPₒ) value of Equation 1 in a range from about 27 to and about 32. As the HSPₒ value increases in the above range, the stripping rate may be increased.

In one or more embodiments, the amine compound may include at least one hydroxyl group. For example, the amine compound may be an alkanol amine compound including one hydroxyl group. In the alkanol amine compound, the hydroxyl group may be located at a terminal or a side chain of the amine compound. The alkanol amine compound may have a molecular weight of about 80 g/mol or less, and an HSPₒ value according to Equation 1 in a range from about 27 to about 32.

In one or more embodiments, the amine compound that may satisfy the above-described molecular weight range and the range of the Hansen solubility parameter according to Equation 1 may be used without a particular limitation. For example, the amine compound may include at least one of monoisopropanol amine, 3-amino-1-propanol, monoethanolamine, or 2-methylaminoethanol. These may be used alone or in a combination thereof.

The amine compound included in the stripper composition according to one or more embodiments may include a primary amine compound. For example, the stripper composition may include at least one of monoisopropanol amine, 3-amino-1-propanol, or monoethanolamine, each of which is the primary amine compound as the amine compound.

In an embodiment, a content (e.g., amount) of the amine compound may be in a range from about 5 wt % about 15 wt % based on a total weight of 100 wt % of the stripper composition. Within the content (e.g., amount) range of the amine compound, stripping performance of the stripper composition may be improved without damaging a layer under the photoresist pattern.

If (e.g., when) the content (e.g., amount) of the amine compound is less than 5 wt %, the stripping performance of the stripper composition may not be sufficiently implemented. If (e.g., when) the content (e.g., amount) of the amine compound exceeds 15 wt %, the layer under the photoresist pattern may be damaged.

The stripper composition according to one or more embodiments of the present invention may include a tetra-ammonium salt.

The tetra-ammonium salt may have strong alkalinity, and may rapidly decompose a cross-linking of the photoresist, thereby dissolving and removing an unexposed portion of a photoresist layer.

The tetra-ammonium salt may include four organic substituents (e.g., each linked to the nitrogen atom of the ammonium cation) and one anion, and the four organic substituents may be each independently an alkyl group or an aryl group. The anion may be a chloride ion, a bromide ion, an iodide ion, or a hydroxide ion.

In one or more embodiments, the tetra-ammonium salt may include at least one of tetramethylammonium hydroxide, tetraethylammonium hydroxide, tetrapropylammonium hydroxide, tetrabutylammonium hydroxide, cetyltrimethylammonium bromide, a benzalkonium chloride, dodecyltrimethylammonium chloride, tetrabutylammonium bromide, tetrabutylammonium iodide, or tetraethylammonium chloride.

In one or more embodiments, a content (e.g., amount) of the tetra-ammonium salt may be in a range from about 1 wt % to about 10 wt % based on the total weight of 100 wt % of the stripper composition. If (e.g., when) the content (e.g., amount) of the tetra-ammonium salt satisfies the above-mentioned range, the stripping performance of the stripping composition may be improved.

If (e.g., when) the content (e.g., amount) of the tetra-ammonium salt is less than 1 wt %, the stripping performance of the stripper composition may not be sufficiently implemented. If (e.g., when) the content (e.g., amount) of the tetra-ammonium salt exceeded 10 wt %, the stripping performance of the stripper composition may not be further enhanced, and productivity may be degraded.

The stripper composition according to one or more embodiments of the present invention may include a cyclic alcohol. The cyclic alcohol may reduce a volatile amount of the stripper composition to control evaporation of the amine compound such as an alkanol amine, thereby maintaining performance of the stripper composition for a long period.

In one or more embodiments, the number of carbon atoms of the cyclic alcohol may be in a range from 4 to 6 in a molecule. The cyclic alcohol may include a hydrocarbon ring or a hetero ring having 4 to 6 carbon atoms in a molecule. The hydrocarbon ring and the hetero ring may be monocyclic or polycyclic.

The hydrocarbon ring may include an aliphatic hydrocarbon ring and an aromatic hydrocarbon ring. The hetero ring may include an aliphatic hetero ring and an aromatic hetero ring.

The hetero ring may include one or more hetero atom such as an oxygen atom (O). If (e.g., when) the hetero ring includes two or more hetero atoms, the two or more hetero atoms may be the same as or different from each other. For example, the cyclic alcohol may include a hetero ring including one or two oxygens as the hetero atom.

In one or more embodiments, the cyclic alcohol may include an aliphatic hydrocarbon ring having 4 to 6 carbon atoms in a molecule, an aromatic hydrocarbon ring, or a hetero ring including one or more hetero atoms as ring-forming atoms. Additionally, the cyclic alcohol may include one hydroxyl group. The cyclic alcohol may be a monohydric alcohol containing one hydroxyl group.

For example, the cyclic alcohol may include at least one of tetrahydrofurfuryl alcohol, furfuryl alcohol, cyclobutanol, cyclopentanol, cyclohexanol or isopropylideneglycerol.

In one or more embodiments, a content (e.g., amount) of the cyclic alcohol may be in a range from about 5 wt % to about 15 wt % based on the total weight of 100 wt % of the stripper composition. Within the above content (e.g., amount) range of the cyclic alcohol, the stripping performance of the stripper composition may be improved without damaging the layer under the photoresist pattern.

If (e.g., when) the content (e.g., amount) of the cyclic alcohol is less than 5 wt %, the evaporation of the amine compound may not be properly controlled, and the stripping performance of the stripper composition may not be sufficiently implemented. Additionally, if (e.g., when) the content (e.g., amount) of the cyclic alcohol exceeds 15 wt %, the layer under the photoresist pattern may be damaged.

The stripper composition according to one or more embodiments of the present invention may include a protic polar organic solvent. The protic polar organic solvent may serve an auxiliary stripping agent when stripping the photoresist pattern, and a dissolved photoresist material may be easily dispersed in the stripper composition by the protic polar organic solvent.

The protic polar organic solvent may include a glycol-based compound. The protic polar organic solvent may include one or more glycol compounds. The glycol compound may promote dispersion of the dissolved photoresist in the stripper composition so that the dissolved photoresist may be rapidly removed.

In one or more embodiments, the glycol compound may be represented by Chemical Formula 1 or Chemical Formula 2.

In one or more embodiments, the glycol compound may be represented by Chemical Formula 1.

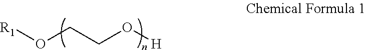

In Chemical Formula 1, R₁ may be hydrogen, a substituted or unsubstituted alkyl group having 1 to 10 carbon atoms, a substituted or unsubstituted cycloalkyl group having 3 to 15 carbon atoms, or a substituted or unsubstituted aryl group having 3 to 15 carbon atoms.

In one or more embodiments, R₁ may be hydrogen, or a substituted or unsubstituted alkyl group having 1 to 10 carbon atoms. For example, R₁ may be hydrogen, a methyl group, an ethyl group, a propyl group, a butyl group, and/or the like.

In Chemical Formula 1, n may be an integer of 1 or greater. For example, n may be an integer of 1 to 10.

In one or more embodiments, the glycol compound may be represented by Chemical Formula 2.

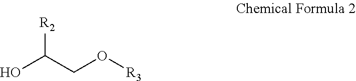

In Chemical Formula 2, R₂ may be hydrogen, or a substituted or unsubstituted alkyl group having 1 to 10 carbon atoms. For example, R₂ may be hydrogen or a methyl group.

In one or more embodiments, R₃ may be hydrogen, a substituted or unsubstituted alkyl group having 1 to 10 carbon atoms, or a substituted or unsubstituted alkoxy group having 1 to 10 carbon atoms. For example, R₃ may be hydrogen, a substituted or unsubstituted methyl group, a substituted or unsubstituted ethyl group, a substituted or unsubstituted propyl group, a substituted or unsubstituted butyl group, a substituted or unsubstituted ethoxy group, and/or the like. When R₃ is substituted with another substituent, R₃ may be substituted with a hydroxyl group, an alkoxy group, and/or the like.

In one or more embodiments, the protic polar organic solvent may include at least one of ethylene glycol, propylene glycol, diethylene glycol monoethyl ether, diethylene glycol monobutyl ether, diethylene glycol monomethyl ether, ethylene glycol monoethyl ether, ethylene glycol monobutyl ether, propylene glycol monomethyl ether, propylene glycol monoethyl ether, propylene glycol monobutyl ether, diethylene glycol monopropyl ether, dipropylene glycol monomethyl ether, dipropylene glycol monoethyl ether, dipropylene glycol monopropyl ether, dipropylene glycol monobutyl ether, triethylene glycol monopropyl ether, triethylene glycol monobutyl ether, triethylene glycol monomethyl ether, tripropylene glycol monoethyl ether, tripropylene glycol monopropyl ether, and tripropylene glycol monobutyl ether. These may be used alone or in a combination thereof. In one or more embodiments, the stripper composition may include diethylene glycol monoethyl ether as the protic polar organic solvent.

In one or more embodiments, a content (e.g., amount) of the protic polar organic solvent may be in a range from about 10 wt % to about 50 wt % based on the total weight of 100 wt % of the stripper composition. In one or more embodiments, the content (e.g., amount) of the protic polar organic solvent may be in a range from about 20 wt % to about 50 wt %, or from about 30 wt % to about 50 wt % based on the total weight of 100 wt % of the stripper composition.

Within the above-described content (e.g., amount) range of the protic polar organic solvent, sufficient swelling and dissolution of the photoresist pattern may be implemented. For example, if (e.g., when) the content (e.g., amount) of the protic polar organic solvent is less than 10 wt %, dissolution capability of the photoresist pattern may not be sufficient. If (e.g., when) the content (e.g., amount) of the protic polar organic solvent exceeds 50 wt %, the stripping performance of the stripper composition may be degraded, and production cost of the stripper composition may be increased.

The stripper composition according to one or more embodiments may include an aprotic polar organic solvent. The aprotic polar organic solvent may reduce bonding strength of a polymer material in the photoresist so that the cured and transformed photoresist pattern may be easily removed. Accordingly, stripping power and cleaning performance of the stripper composition may be further improved.

Any compound having a solubility for the photoresist pattern excluding hazardous substances may be used without particular limitation as the aprotic polar organic solvent. For example, the aprotic polar organic solvent may not include (e.g., may exclude) N-methyl-2-pyrrolidinone and N-methylformamide which are hazardous to environment and human body. In one or more embodiments, the stripper composition may enhance solubility of the photoresist pattern without using N-methyl-2-pyrrolidone and/or N-methylformamide, which are hazardous substances, as the aprotic polar organic solvent.

For example, the aprotic polar organic solvent may include at least one of 2-pyrrolidone, 4-formylmorpholine, N,N-dimethyl propionamide, 1,3-dimethyl-2-imidazolidinone, N,N-dimethylacetoacetamide, sulfolane, N-ethylformamide, or 3-methoxy N,N-dimethylpropanamide (Equamide). These may be used alone or in a combination thereof. The stripper composition according to one or more embodiments may include N,N-dimethyl propionamide as the aprotic polar organic solvent.

In one or more embodiments, a content (e.g., amount) of the aprotic polar organic solvent may be in a range from about 10 wt % to about 50 wt % based on the total weight of 100 wt % of the stripper composition. In one or more embodiments, the content (e.g., amount) of the aprotic polar organic solvent may be in a range from about 20 wt % to about 50 wt %, or from about 30 wt % to about 50 wt % based on the total weight of 100 wt % of the stripper composition.

Within the above-described content (e.g., amount) range of the aprotic polar organic, the stripping power for a cured or modified photoresist may be improved, and the solubility for the stripped photoresist may be enhanced. For example, if (e.g., when) the content (e.g., amount) of the aprotic polar organic solvent is less than 10 wt %, removing capability for the modified photoresist may not be sufficient. If (e.g., when) the content (e.g., amount) of the aprotic polar organic solvent exceeds 50 wt %, the stripping performance of the stripper composition may be degraded, and the production cost of the stripper composition may be increased.

The stripping composition may include a polyhydric alcohol. The polyhydric alcohol may improve cleaning performance of the stripper composition. Corrosion of a metal layer such as an aluminum layer and damages to a metal oxide layer may be suppressed or reduced by the polyhydric alcohol in a rinse process.

The stripping composition containing a polyhydric alcohol having 3 or less carbon atoms may be hazardous to explosion under certain conditions. In one or more embodiments, the polyhydric alcohol may have 4 or more carbon atoms in a molecule. For example, in one or more embodiments, the polyhydric alcohol may have 4 to 6 carbon atoms in a molecule. The polyhydric alcohol may be a linear alkyl alcohol having 4 to 6 carbon atoms. The term “linear alkyl” as used herein may refer to a straight-chain alkyl or a branched-chain alkyl.

For example, the linear alkyl alcohol may include at least three hydroxyl groups connected to a straight-chain alkyl group having 4 to 6 carbon atoms. The linear alkyl alcohol having 4 to 6 carbon atoms includes all racemic forms or stereoisomers thereof.

For example, the polyhydric alcohol may include at least one of erythritol, threitol, arabitol, xylitol, ribitol, mannitol, sorbitol, galactitol, fucitol, or iditol. In the rinsing process, as an order of the alcohol increases, a surface area of the alcohol molecule may become greater to increase an intermolecular force. Accordingly, the stripper composition according to one or more embodiments including the polyhydric alcohol may provide further improved cleaning performance. Additionally, the stripping composition according to one or more embodiments may stabilize a surface of the metal layer in the rinsing process by including the polyhydric alcohol, and may provide more effective anti-corrosion performance.

In one or more embodiments, a content (e.g., amount) of the polyhydric alcohol may be in a range from about 0.05 wt % to about 1 wt % based on the total weight of 100 wt % of the stripper composition. Within the above-described content (e.g., amount) range of the polyhydric alcohol, stripping of the photoresist pattern may be implemented without causing surface damages to the layer under of the photoresist.

For example, if (e.g., when) the content (e.g., amount) of the polyhydric alcohol is less than 0.05 wt %, cleaning and anti-corrosion prevention performance of the stripper composition may be degraded. If (e.g., when) the content (e.g., amount) of the polyhydric alcohol exceeds 1 wt %, insoluble components may be generated. Accordingly, residues of the stripper composition may be generated, and residues generated from the photoresist may also be present.

The stripper composition according to one or more embodiments may not contain water. The stripper composition according to one or more embodiments may be a non-aqueous stripper composition. Water may contain deionized water (ultra-pure water).

The stripper composition according to one or more embodiments may provide an increased stripping capability with respect to the photoresist without damaging the layer under the photoresist such as a metal layer, a metal oxide layer, or a combination thereof, and may remove the photoresist in a short period.

Additionally, the stripper composition according to one or more embodiments may have an increased solubility of the photoresist, and the stripping capability may be increased, thereby improving process productivity. The stripper composition may have an increased cleaning capability and may not cause a residual liquid or surface impurities after stripping the photoresist pattern. Accordingly, production yield of a fabrication of a semiconductor device and a display device may be increased by using the stripper composition.

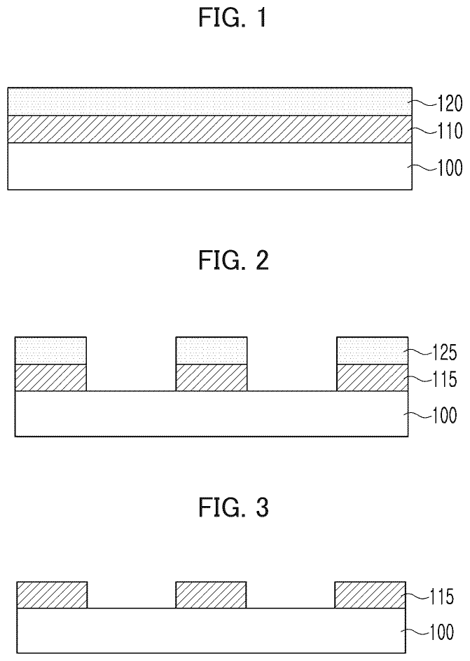

FIGS. 1 to 3 are schematic cross-sectional views describing a method of forming a pattern according to one or more embodiments of the present disclosure.

Referring to FIG. 1, an etching target layer 110 may be formed on a substrate 100, and a photoresist layer 120 may be formed on the etching target layer 110.

In one or more embodiments, the substrate 100 may include a semiconductor substrate such as a silicon wafer.

In one or more embodiments, the etching target layer 120 may be formed of a metal layer and/or a metal oxide layer.

The photoresist layer 120 may be formed on the substrate 100 by a coating process such as spin coating or slit coating using a photoresist composition including a photosensitive polymer. For example, the photoresist composition may be coated, and then the photoresist layer 120 may be formed by a soft-baking process.

Referring to FIG. 2, the photoresist layer 120 may be partially removed by exposure and development processes to form a photoresist pattern 125. Thereafter, a post-baking process may be further performed on the photoresist pattern 125.

The etching target layer 110 may be partially removed by using the photoresist pattern 125 as an etching mask. Accordingly, a target pattern 115 may be formed from the etching target layer 110. In one or more embodiments, the target pattern 115 may include a metal wiring.

Referring to FIG. 3, the photoresist pattern 125 may be removed using the above-described stripper composition according to one or more embodiments of the present disclosure.

The photoresist pattern 125 may be rapidly peeled off using the stripper composition with an improved stripping capability. Further, the target pattern 115 may remain on the substrate 100 without causing residues of the stripper composition and/or the photoresist pattern 125.

Hereinafter, one or more embodiments of the present disclosure s will be described in more detail with reference to Experimental Examples including Examples and Comparative Examples. The Examples are provided to assist in understanding the disclosure, but they are provided as non-limiting examples, and the scope of the disclosure is not limited thereto. It will be clear to those skilled in the art that one or more suitable changes and modifications to disclosed examples can be made within the scope of the disclosure.

### EXAMPLES AND COMPARATIVE EXAMPLES

### 1. Evaluation Example 1

Stripper compositions of Examples 1-1 and 1-2, and the stripper compositions of Comparative Examples 1-1 to 1-3 were each prepared according to components and contents (i.e., amounts) as shown in Table 1. In Table 1, a unit indicating the content (e.g., amount) of each component represents wt % based on 100% of a total weight of the stripper composition, and “sec” refers to a unit of time in second.

Results of the stripping performance evaluation for each of the stripper compositions of Examples 1-1, 1-2, and Comparative Examples 1-1 to 1-3 are also shown in Table 1. In Table 1, a stripping time (sec) indicates a time for stripping a negative organic layer pattern to be stripped by the stripper composition.

For example, a negative organic layer (acrylate-based, having a film thickness of about 20 μm to 90 μm) was coated on a top surface of a glass substrate. The negative organic layer was formed to have a thickness of 1.6 micrometers (μm) by a heat treatment in an oven at 100° C. for 110 seconds and then at 260° C. for 30 minutes. While maintaining the stripper composition at 60° C., the substrate on which the negative organic layer was formed was immersed in the stripper composition to measure a time for removing the cured negative organic layer.

Molecular weights of amine compounds used in Examples 1-1, 1-2, and Comparative Examples 1-1 to 1-3, and Hansen Solubility parameter (HSPₒ) values according to Equation 1 are shown in Table 2.

TABLE 1

| | | | | Comparative | Comparative | Comparative |
|---|---|---|---|---|---|---|
| | | Example | Example | Example | Example | Example |
| | | 1-1 | 1-2 | 1-1 | 1-2 | 1-3 |
| amine | MEA | 12 | — | — | — | — |
| compound | MIPA | — | 12 | — | — | — |
| | NMEA | — | — | 12 | — | — |
| | MDEA | — | — | — | 12 | — |
| | AB | — | — | — | — | 12 |
| tetra- | TMAH(s) | 2 | 2 | 2 | 2 | 2 |
| ammonium | | | | | | |
| salt | | | | | | |
| protic | EDG | 35.5 | 35.5 | 35.5 | 35.5 | 35.5 |
| polar | | | | | | |
| organic | | | | | | |
| solvent | | | | | | |
| aprotic | DMPA | 40 | 40 | 40 | 40 | 40 |
| polar | | | | | | |
| organic | | | | | | |
| solvent | | | | | | |
| cyclic | IPG | 10 | 10 | 10 | 10 | 10 |
| alcohol | | | | | | |
| polyhydric | SBT | 0.5 | 0.5 | 0.5 | 0.5 | 0.5 |
| alcohol | | | | | | |

| | | | | | |
|---|---|---|---|---|---|
| stripping time | 120 sec | 120 sec | 240 sec | 240 sec | 240 sec |

MEA: monoethanolamine
MIPA: monoisopropanolamine
NMEA: 2-(methylamino)ethanol
MDEA: N-methyldiethanolamine
AB: 2-amino-1-butanol
IPG: 1,2-isopropylideneglycerol
EDG: diethylene glycol monoethyl ether
DMPA: N,N-dimethylpropionamide
TMAH: tetramethylammonium hydroxide
SBT: sorbitol

TABLE 2

| amine | molecular | Hansen Solubility Parameters | | | |
|---|---|---|---|---|---|
| compound | weight (MW) | HSPₒ | HSP_{d} | HSPₚ | HSPₕ |
| AB | 89.14 | 24.1 | 16.9 | 7.5 | 15.4 |
| MIPA | 75.11 | 27.8 | 15.8 | 9.4 | 20.9 |
| MEA | 61.08 | 31.3 | 17 | 15.5 | 21.2 |
| NMEA | 75.11 | 24.7 | 16.1 | 12.3 | 14.1 |
| MDEA | 119.16 | 28.3 | 16.9 | 11.1 | 19.8 |

Referring to Table 1 and Table 2, the negative organic layer was removed in a shorter time by using each of the stripper compositions of Examples in which the amine compound having the molecular weight of 80 g/mol or less and the Hansen Solubility parameter (HSPₒ) value in a range from 27 to 32 according to Equation 1 compared to the case using the stripper compositions of Comparative Examples.

For example, in Examples 1-1 and 1-2, the photoresist pattern was stripped within 120 seconds. Referring to the stripping time evaluation results of Example 1-2 and Comparative Example 1-1, the stripping time became shorter as the HSPₒ value increased. Referring to the stripping time evaluation results of Example 1-1 and Comparative Example 1-2, the stripping time became shorter as the molecular weight decreased.

In Comparative Examples 1-1, 1-2, and 1-3 where the HSPₒ value of the amine compound included in the stripper composition was not in the range of 27 to 32 or the molecular weight exceeded 80 g/mol, the stripping time increased compared to those from Examples.

In Comparative Example 1-2 where the HSPₒ value of the amine compound included in the stripper composition was in the range of 27 to 32, but the molecular weight exceeded 80 g/mol, the stripping time increased compared to those from Examples.

In Comparative Example 1-1 where the molecular weight of the amine compound included in the stripper composition is 80 g/mol or less, but the HSPₒ value of the amine compound was less than 27, the stripping time increased compared to those from Examples.

### 2. Evaluation Example 2

The stripper compositions of Examples 2-1 to 2-5 and the stripper compositions of Comparative Examples 2-1 to 2-3 were each prepared according to components and contents as shown in Table 3. In Table 3, a unit indicating the content (e.g., amount) of each component represents wt % based on 100% of the total weight of the stripper composition, and “sec” refers to a unit of time in second.

Table 3 shows the results of the stripping performance evaluation for each of the stripper compositions of Examples 2-1 to 2-5 and Comparative Examples 2-1 to 2-3. In the stripping performance evaluation in Table 3, the substrate including the negative organic layer with a thickness of 1.6 μm prepared in Evaluation Example 1 was immersed in one of the stripper compositions of Examples and Comparative Examples for a maximum of 600 seconds, and a time for completely removing the negative organic layer was measured.

TABLE 3

| | | | | | | | Comparative | Comparative | Comparative |
|---|---|---|---|---|---|---|---|---|---|
| | | Example | Example | Example | Example | Example | Example | Example | Example |
| | | 2-1 | 2-2 | 2-3 | 2-4 | 2-5 | 2-1 | 2-2 | 2-3 |
| amine | MEA | 12 | 12 | 12 | 12 | 12 | 12 | 12 | 12 |
| compound | | | | | | | | | |
| tetra- | TMAH | 1 | 2 | 5 | 8 | 10 | 0 | 0.5 | 15 |
| ammonium | (s) | | | | | | | | |
| salt | | | | | | | | | |
| protic | EDG | 36.5 | 35.5 | 32.5 | 29.5 | 27.5 | 37.5 | 37 | 22.5 |
| polar | | | | | | | | | |
| organic | | | | | | | | | |
| solvent | | | | | | | | | |
| aprotic | DMPA | 40 | 40 | 40 | 40 | 40 | 40 | 40 | 40 |
| polar | | | | | | | | | |
| organic | | | | | | | | | |
| solvent | | | | | | | | | |
| cyclic | IPG | 10 | 10 | 10 | 10 | 10 | 10 | 10 | 10 |
| alcohol | | | | | | | | | |
| polyhydric | SBT | 0.5 | 0.5 | 0.5 | 0.5 | 0.5 | 0.5 | 0.5 | 0.5 |
| alcohol | | | | | | | | | |

| | | | | | | | | |
|---|---|---|---|---|---|---|---|---|
| stripping time | 120 sec | 120 sec | 60 sec | 30 sec | 10 sec | X | X | 10 sec |

MEA: monoethanolamine
IPG: 1,2-isopropylideneglycerol
EDG: diethylene glycol monoethyl ether
DMPA: N,N-dimethylpropionamide
TMAH: tetramethylammonium hydroxide
SBT: sorbitol

Referring to Table 3, the negative organic layer was stripped in each of the composition in which the content (e.g., amount) of the tetra-ammonium salt was 1 wt % or more.

Referring to Examples 2-1 to 2-5 and Comparative Example 2-3, the stripping rate increased as the content (e.g., amount) of the tetra-ammonium salt increased to 10 wt %. When the content (e.g., amount) of the tetra-ammonium salt exceeded 10 wt %, the stripping rate was not further increased.

As utilized herein, the terms “and/or” and “or” may include any and all combinations of one or more of the associated listed items. The “/” utilized below may be interpreted as “and” or as “or” depending on the situation. In the present disclosure, expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof.

It will be further understood that the terms “comprise(s)/comprising”, “include(s)/including,” or “have/has/having,” when utilized in the present disclosure, specify the presence of stated features, numbers, steps, operations, elements, and/or components, but do not preclude the presence or addition of one or more other features, numbers, steps, operations, elements, components, and/or groups thereof. Additionally, the terms “comprise(s)/comprising,” “include(s)/including,” “have/has/having,” or other similar terms include or support the terms “consisting of” and “consisting essentially of,” indicating the presence of stated features, numbers, steps, operations, elements, and/or components, without or essentially without the presence of other features, numbers, steps, operations, elements, components, and/or groups thereof.

As utilized herein, the singular forms “a,” “an,” and “the” are intended to include the plural forms as well, unless the context clearly indicates otherwise. Further, the utilization of “may” when describing embodiments of the present disclosure refers to “one or more embodiments of the present disclosure”.

In the context of the present disclosure and unless otherwise defined, the terms “use,” “using,” and “used” may be considered synonymous with the terms “utilize,” “utilizing,” and “utilized,” respectively.

As utilized herein, the term “about,” or similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, ±20%, ±10%, or ±5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

A pattern forming device, a semiconductor forming device, a display panel and/or display device forming device, an electronic device including the semiconductor, the display panel, and/or the display device, and/or any other relevant devices or components according to embodiments of the present invention described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

Hereinbefore, certain embodiments of the present disclosure have been described and illustrated, however, it is apparent to a person with ordinary skill in the art that the present disclosure is not limited to the presented embodiment as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure. It is further to be understood that the scope of the present disclosure is defined by the appended claims and equivalents thereof rather than the detailed description described above, and all modifications and alterations derived from the claims and their equivalents fall within the scope of the present disclosure.

What is claimed is:

1. A stripper composition, comprising:
5 wt % to 15 wt % of an amine compound having a molecular weight of 80 g/mol or less and a Hansen Solubility parameter (HSPₒ) value defined by Equation 1 in a range from 27 to 32;
1 wt % to 10 wt % of a tetra-ammonium salt;
5 wt % to 15 wt % of a cyclic alcohol;
10 wt % to 50 wt % of a protic polar organic solvent;
10 wt % to 50 wt % of an aprotic polar organic solvent; and
0.05 wt % to 1 wt % a polyhydric alcohol having 4 to 6 carbon atoms, based on a total weight of 100 wt % of the stripper composition:
$$H S {P}_{o} = {( H S {P}_{d}^{2} + H S {P}_{p}^{2} + H S {P}_{h}^{2} )}^{0.5} , \qquad Equation 1$$
wherein, in Equation 1, HSP_{d} represents a solubility factor caused by a nonpolar dispersion bonding, HSPₚ represents a solubility factor caused by a polar bonding due to permanent dipoles, and HSPₕ represents a solubility factor caused by a hydrogen bonding.

2. The stripper composition of claim 1, wherein the amine compound comprises an alkanol amine compound.

3. The stripper composition of claim 1, wherein the amine compound comprises at least one of monoisopropanolamine, 3-amino-1-propanol, monoethanolamine, or 2-methylaminoethanol.

4. The stripper composition of claim 1, wherein the amine compound comprises a primary amine compound.

5. The stripper composition of claim 1, wherein the tetra-ammonium salt comprises four organic substituents and one anion,
wherein the four organic substituents are each independently an alkyl group or an aryl group, and
wherein the anion is a chloride ion, a bromide ion, an iodide ion, or a hydroxide ion.

6. The stripper composition of claim 1, wherein the tetra-ammonium salt comprises at least one of tetramethylammonium hydroxide, tetraethylammonium hydroxide, tetrapropylammonium hydroxide, tetrabutylammonium hydroxide, cetyltrimethylammonium bromide, a benzalkonium chloride, dodecyltrimethylammonium chloride, tetrabutylammonium bromide, tetrabutylammonium iodide, or tetraethylammonium chloride.

7. The stripper composition of claim 1, wherein the number of carbons of the cyclic alcohol is in a range from 4 to 6.

8. The stripper composition of claim 1, wherein the cyclic alcohol comprises at least one of tetrahydrofurfuryl alcohol, furfuryl alcohol, cyclobutanol, cyclopentanol, cyclohexanol, or isopropylideneglycerol.

9. The stripper composition of claim 1, wherein the protic polar organic solvent comprises a glycol-based compound represented by Chemical Formula 1 or Chemical Formula 2: 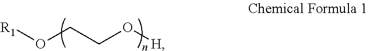
wherein, in Chemical Formula 1, R₁ is hydrogen, a substituted or unsubstituted alkyl group having 1 to 10 carbon atoms, a substituted or unsubstituted cycloalkyl group having 3 to 15 carbon atoms, or a substituted or unsubstituted aryl group having 3 to 15 carbon atoms, and n is an integer of 1 or greater, 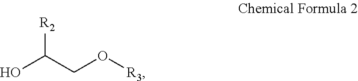
and
wherein, in Chemical Formula 2, R₂ is hydrogen, a substituted or unsubstituted alkyl group having 1 to 10 carbon atoms, and R₃ is hydrogen, a substituted or unsubstituted alkyl group having 1 to 10 carbon atoms, or a substituted or unsubstituted alkoxy group having 1 to 10 carbon atoms.

10. The stripper composition of claim 1, wherein the protic polar organic solvent comprises at least one of ethylene glycol, propylene glycol, diethylene glycol monoethyl ether, diethylene glycol monobutyl ether, diethylene glycol monomethyl ether, ethylene glycol monoethyl ether, ethylene glycol monobutyl ether, propylene glycol monomethyl ether, propylene glycol monoethyl ether, propylene glycol monobutyl ether, diethylene glycol monopropyl ether, dipropylene glycol monomethyl ether, dipropylene glycol monoethyl ether, dipropylene glycol monopropyl ether, dipropylene glycol monobutyl ether, triethylene glycol monopropyl ether, triethylene glycol monobutyl ether, triethylene glycol monomethyl ether, tripropylene glycol monoethyl ether, tripropylene glycol monopropyl ether, or tripropylene glycol monobutyl ether.

11. The stripper composition of claim 1, wherein the stripper composition does not comprise N-methyl-2-pyrrolidone and N-methylformamide.

12. The stripper composition of claim 1, wherein the aprotic polar organic solvent comprises at least one of 2-pyrrolidone, 4-formylmorpholine, N,N-dimethyl propionamide, 1,3-dimethyl-2-imidazolidinone, N,N-dimethylacetoacetamide, sulfolane, n-ethylformamide, or 3-methoxy N,N-dimethylpropanamide.

13. The stripper composition of claim 1, wherein the polyhydric alcohol is a linear alkyl alcohol.

14. The stripper composition of claim 1, wherein the polyhydric alcohol comprises at least one of erythritol, threitol, arabitol, xylitol, ribitol, mannitol, sorbitol, galactitol, fucitol, or iditol.

15. The stripper composition of claim 1, wherein the stripper composition does not comprise water.

16. A method, comprising:
forming an etching target layer on a substrate;
forming a photoresist pattern on the etching target layer;
etching the etching target layer utilizing the photoresist pattern; and
removing the photoresist pattern utilizing a stripper composition,
wherein the stripper composition comprises:
5 wt % to 15 wt % of an amine compound having a molecular weight of 80 g/mol or less and a Hansen Solubility parameter (HSPₒ) value defined by Equation 1 in a range from 27 to 32;
1 wt % to 10 wt % of a tetra-ammonium salt;
5 wt % to 15 wt % of a cyclic alcohol;
10 wt % to 50 wt % of a protic polar organic solvent;
10 wt % to 50 wt % of an aprotic polar organic solvent; and
0.05 wt % to 1 wt % a polyhydric alcohol having 4 to 6 carbon atoms, based on a total weight of 100 wt % of the stripper composition:
$$H S {P}_{o} = {( H S {P}_{d}^{2} + H S {P}_{p}^{2} + H S {P}_{h}^{2} )}^{0.5} , \qquad Equation 1$$
wherein, in Equation 1, HSP_{d} represents a solubility factor caused by a nonpolar dispersion bonding, HSPₚ represents a solubility factor caused by a polar bonding due to permanent dipoles, and HSPₕ represents a solubility factor caused by a hydrogen bonding, and
wherein the method is a method of forming a pattern.

17. An electronic device comprising a substrate having a pattern formed thereon, wherein the pattern is formed by the method of claim 16.

18. An electronic device comprising a substrate having a photoresist pattern removed therefrom, wherein the photoresist pattern is removed utilizing the stripper composition of claim 1.
